(19) United States
(12) Patent Application Publication
(10) Pub. No.: US 2024/0412976 A1
(43) Pub. Date: Dec. 12, 2024

(54) SUBSTRATE PROCESSING APPARATUS AND SUBSTRATE PROCESSING METHOD

(71) Applicant: Tokyo Electron Limited, Tokyo (JP)

(72) Inventors: Susumu HAYAKAWA, Kikuchi-gun, Kumamoto (JP); Takashi SAKAUE, Kikuchi-gun, Kumamoto (JP)

(21) Appl. No.: 18/704,093

(22) PCT Filed: Oct. 12, 2022
(86) PCT No.: PCT/JP2022/038083

§ 371 Date: Apr. 24, 2024

(30) Foreign Application Priority Data
Oct. 26, 2021 (JP) 2021-174767

(51) Int. Cl. H01L 21/304; B24B 7/10; G03F 7/16; H01L 21/66

(52) U.S. Cl. CPC H01L 21/304; B24B 7/10; G03F 7/162; H01L 22/12

(57) ABSTRACT

A substrate processing apparatus includes a film forming device configured to form a film on a non-bonding surface of a second substrate, which has a bonding surface bonded to a first substrate to be thinned and the non-bonding surface opposite to the bonding surface; and a controller configured to control the film forming device. The controller performs a control of forming the film on a portion of the non-bonding surface or forming the film thicker on a portion of the non-bonding surface than on another portion thereof, based on a thickness distribution of the second substrate.

### TECHNICAL FIELD

The various aspects and embodiments described herein pertain generally to a substrate processing apparatus and a substrate processing method.

### BACKGROUND

A substrate processing system described in Patent Document 1 includes a bonding apparatus configured to bond a first substrate and a second substrate, and a plate thickness reducing apparatus configured to reduce a thickness of the first substrate in a combined substrate formed by the bonding in the bonding apparatus. The plate thickness reducing apparatus is, for example, a grinding device.

### PRIOR ART DOCUMENT

Patent Document 1: Japanese Patent Laid-open Publication No. 2021-103698

### DISCLOSURE OF THE INVENTION

### Problems to be Solved by the Invention

Exemplary embodiments provide a technique capable of reducing unevenness in the thickness of a first substrate after being thinned.

### Means for Solving the Problems

In an exemplary embodiment, a substrate processing apparatus includes a film forming device configured to form a film on a non-bonding surface of a second substrate, which has a bonding surface bonded to a first substrate to be thinned and the non-bonding surface opposite to the bonding surface; and a controller configured to control the film forming device. The controller performs a control of forming the film on a portion of the non-bonding surface or forming the film thicker on a portion of the non-bonding surface than on another portion thereof, based on a thickness distribution of the second substrate.

### EFFECT OF THE INVENTION

According to the exemplary embodiment, it is possible to reduce unevenness in the thickness of the first substrate after being thinned.

### BRIEF DESCRIPTION OF THE DRAWINGS

FIG. 1A to FIG. 1C are cross sectional views illustrating a substrate processing method according to a reference embodiment: FIG. 1A is a cross sectional view showing a state of a combined substrate before being thinned; FIG. 1B, a cross sectional view showing a state of the combined substrate being thinned; and FIG. 1C, a cross sectional view showing a state of the combined substrate after being thinned.

FIG. 2 is a plan view illustrating a bonding surface of a first substrate and a bonding surface of a second substrate according to the reference embodiment.

FIG. 3A to FIG. 3D are cross sectional views illustrating a substrate processing method according to an exemplary embodiment: FIG. 3A is a cross sectional view illustrating measurement of a thickness distribution of a second substrate; FIG. 3B, a cross sectional view illustrating film formation; FIG. 3C, a cross sectional view illustrating thinning; and FIG. 3D, a cross sectional view illustrating a state of a combined substrate after being thinned.

FIG. 4 is a plan view illustrating a non-bonding surface of the second substrate according to the exemplary embodiment.

FIG. 5A to FIG. 5C are cross sectional views illustrating an example of the film formation using a photosensitive material: FIG. 5A is a cross sectional view illustrating coating of the photosensitive material; FIG. 5B, a cross sectional view illustrating exposure; and FIG. 5C, a cross sectional view illustrating development.

FIG. 6A and FIG. 6B are cross sectional views illustrating an example of the film formation using an ink material: FIG. 6A is a cross sectional view illustrating coating of the ink material by an ink jet head, and FIG. 6B is a cross sectional view illustrating the coating of the ink material by an ink pen.

FIG. 7 is a plan view illustrating a substrate processing apparatus according to the exemplary embodiment.

FIG. 8A to FIG. 8D are cross sectional views illustrating a substrate processing method according to a modification example: FIG. 8A is a cross sectional view illustrating measurement of a thickness distribution of a second substrate; FIG. 8B, a cross sectional view illustrating formation of a recess; FIG. 8C, a cross sectional view illustrating thinning; and FIG. 8D, a cross sectional view illustrating a state of a combined substrate after being thinned.

### DETAILED DESCRIPTION

Hereinafter, exemplary embodiments of the present disclosure will be described with reference to the accompanying drawings. In the various drawings, same or corresponding parts will be assigned same or corresponding reference numerals, and redundant description will be omitted. In the present specification, the X-axis direction, the Y-axis direction and the Z-axis direction are orthogonal to each other. The X-axis and Y-axis directions are horizontal directions, and the Z-axis direction is a vertical direction.

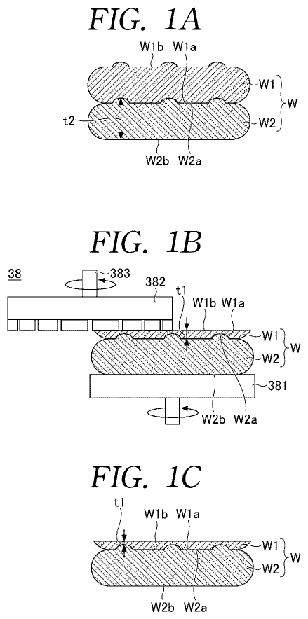

First, referring to FIG. 1A to FIG. 1C, a substrate processing method according to a reference embodiment will be described. First, a combined substrate W is prepared as shown in FIG. 1A. The combined substrate W includes a first substrate W1 to be thinned and a second substrate W2 bonded to the first substrate W1. The first substrate W1 has a bonding surface W1a bonded to the second substrate W2, and a non-bonding surface W1b opposite to the bonding surface W1a. Likewise, the second substrate W2 has a bonding surface W2a bonded to the first substrate W1, and a non-bonding surface W2b opposite to the bonding surface W2a.

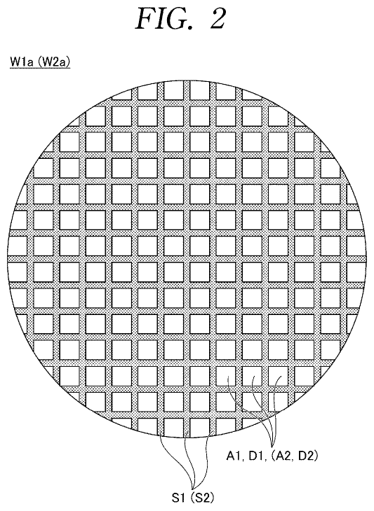

The first substrate W1 includes, for example, a silicon wafer, a compound semiconductor wafer, or a glass substrate. As shown in FIG. 2, the first substrate W1 has a plurality of streets S1 arranged in, for example, a square grid pattern on the bonding surface W1a of the first substrate W1; and devices D1 formed in device areas A1 partitioned by the plurality of streets S1. The device D1 includes, for example, an electronic circuit.

The second substrate W2 has the same structure as the first substrate W1. That is, the second substrate W2 includes, for example, a silicon wafer, a compound semiconductor wafer, or a glass substrate. As shown in FIG. 2, the second substrate W2 has a plurality of streets S2 arranged in, for example, a square grid pattern on the bonding surface W2a of the second substrate W2; and devices D2 formed in device areas A2 partitioned by the plurality of streets S2. The device D2 includes, for example, an electronic circuit.

By bonding the first substrate W1 and the second substrate W2 with the bonding surface W1a of the first substrate W1 facing the bonding surface W2a of the second substrate W2, the device D1 of the first substrate W1 and the device D2 of the second substrate W2 are electrically connected. Afterwards, the first substrate W1 is thinned as shown in FIG. 1B, and the combined substrate W is then split into a plurality of semiconductor chips by dicing. As a result, it is possible to achieve thinner semiconductor chips with higher performance.

As shown in FIG. 1A, however, the second substrate W2 may have an uneven thickness t2. The unevenness of the thickness t2 is expressed as a difference (TTV: Total Thickness Variation) between a maximum value and a minimum value of the thickness t2. The unevenness in the thickness t2 of the second substrate W2 depends on, for example, the thickness of the device D2 on the bonding surface W2a of the second substrate W2.

As illustrated in FIG. 1B, a thinning apparatus 38 thins the first substrate W1. By way of example, the thinning apparatus 38 includes a substrate holder 381 configured to attract the combined substrate W, and a grindstone driving device 383 configured to drive a grindstone 382 from the opposite side to the substrate holder 381. An attraction surface of the substrate holder 381 has a size equal to or larger than a main surface of the combined substrate W, and serves to attract the entire combined substrate W. The substrate holder 381 is, for example, a vacuum chuck, and is configured to vacuum-attract the combined substrate W.

The substrate holder 381 attracts the non-bonding surface W2b of the second substrate W2 in a flat manner. For this reason, when the thickness of the second substrate W2 is non-uniform, minute irregularities may be formed on the bonding surface W2a of the second substrate W2, and the bonding surface W1a of the first substrate W1 may also be given minute irregularities. The non-bonding surface W1b of the first substrate W1 is processed parallel to the non-bonding surface W2b of the second substrate W2.

Accordingly, as illustrated in FIG. 1C, a thickness t1 of the first substrate W1 after being thinned becomes non-uniform. As a result, problems occur in a post-process such as formation of an electrode. The electrode is formed on the non-bonding surface W1b of the first substrate W1, and is electrically connected to the device D1 formed on the bonding surface W1a of the first substrate W1.

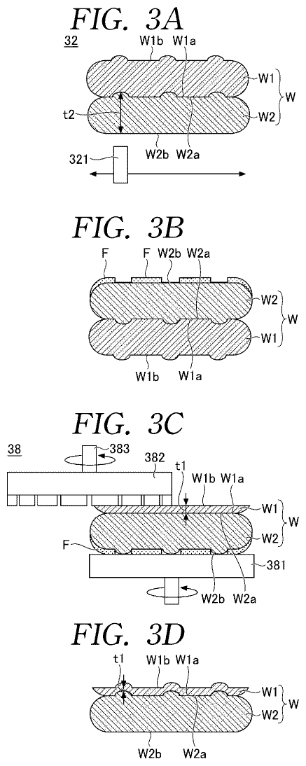

Now, referring to FIG. 3A to FIG. 3D, a substrate processing method according to an exemplary embodiment will be described. First, as shown in FIG. 3A, the measuring apparatus 32 measures a thickness distribution of the second substrate W2. The measurement data includes coordinates on the non-bonding surface W2b of the second substrate W2 and the thickness t2 of the second substrate W2 for each coordinate. For example, the measuring apparatus 32 uses infrared light that penetrates the second substrate W2, and measures the thickness distribution of the second substrate W2 by using interference between the light reflected from the non-bonding surface W2b of the second substrate W2 and the light reflected from the bonding surface W2a of the second substrate W2.

The measuring apparatus 32 includes, for example, a probe 321 configured to vertically radiate the infrared light toward the non-bonding surface W2b of the second substrate W2 and receive the light reflected from the second substrate W2, a light source connected to the probe 321 via an optical fiber, a photodetector connected to the probe 321 via an optical fiber, and a moving mechanism configured to move the probe 321 relative to the second substrate W2. Further, although the non-bonding surface W2b of the second substrate W2 is illustrated as facing downwards in FIG. 3A, it may face upwards, and the combined substrate W may be upside down.

Furthermore, in the present exemplary embodiment, although the measuring apparatus 32 measures the thickness distribution of the second substrate W2 after the first substrate W1 and the second substrate W2 are bonded, the thickness distribution of the second substrate W2 may be measured before the first substrate W1 and the second substrate W2 are bonded. In the latter case, it may be also possible to measure the thickness distribution of the second substrate W2 by measuring a distance to the bonding surface W2a of the second substrate W2 with a capacitive displacement sensor or a laser displacement sensor. Further, in the latter case, it may be also possible to use a contact sensor.

Subsequently, as illustrated in FIG. 3B, a film F is formed on a portion of the non-bonding surface W2b of the second substrate W2 based on the thickness distribution of the second substrate W2. The formation of the film F is performed under a control of a control device 90 to be described later. The control device 90 allows the film F to be formed at a position where the thickness t2 of the second substrate W2 is the minimum but not to be formed at a position where the thickness t2 of the second substrate W2 is the maximum.

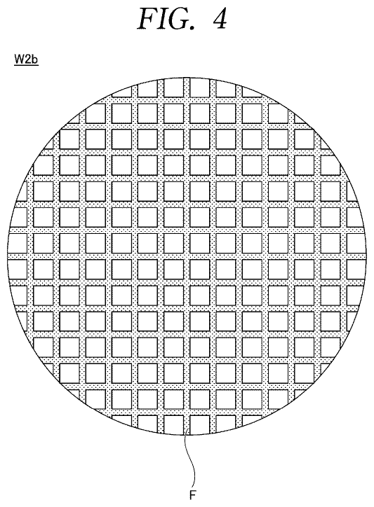

For example, when the thickness of the second substrate W2 in the street S2 is smaller than the thickness of the second substrate W2 in the device area A2, the control device 90 forms the film F in a square grid pattern along the plurality of streets S2 (see FIG. 4). Further, when the thickness of the second substrate W2 in the device area A2 is smaller than the thickness of the second substrate W2 in the street S2, the control device 90 forms the film F in an island shape for each device area A2.

The thickness of the film F varies depending on the difference (TTV) between the maximum value and the minimum value of the thickness t2 of the second substrate W2. The larger the TTV is, the larger the thickness of the film F is set to be.

In addition, although the film F is formed after the bonding of the first substrate W1 and the second substrate W2 in the present exemplary embodiment, the film F may be formed before the bonding of the first substrate W1 and the second substrate W2.

Next, as shown in FIG. 3C, in the state that the film F is formed on the portion of the non-bonding surface W2b of the second substrate W2, the thinning apparatus 38 thins the first substrate W1 previously bonded to the second substrate W2. The substrate holder 381 attracts the second substrate W2 through the film F to elastically transform the second substrate W2. The second substrate W2 is elastically transformed such that a portion of the second substrate W2 enters an opening of the film F.

As a result, the bonding surface W2a of the second substrate W2 is planarized, and the bonding surface W1a of the first substrate W1 is also planarized. In this state, the thinning apparatus 38 processes the non-bonding surface W1b of the first substrate W1 parallel to the bonding surface W1a of the first substrate W1 by using the grindstone 382. As a result, the thickness t1 of the first substrate W1 after being thinned becomes uniform, as illustrated in FIG. 3D. As compared to the reference embodiment, the unevenness in the thickness t1 of the first substrate W1 after being thinned can be reduced.

Furthermore, a non-illustrated laser processing device may be used to thin the first substrate W1. The laser processing device forms a modification layer inside the first substrate W1. A plurality of such modification layers are formed at certain intervals therebetween in a radial direction and a circumferential direction of the first substrate W1. By separating the first substrate W1 starting from the plurality of modification layers, the first substrate W1 can be thinned. In this case as well, if the bonding surface W2a of the second substrate W2 is planarized by attracting the second substrate W2 through the film F, and then, the non-bonding surface W1b of the first substrate W1 is planarized, the modification layer can be formed at a certain depth from the non-bonding surface W1b. As a result, the unevenness in the thickness t1 of the first substrate W1 after being thinned can be reduced.

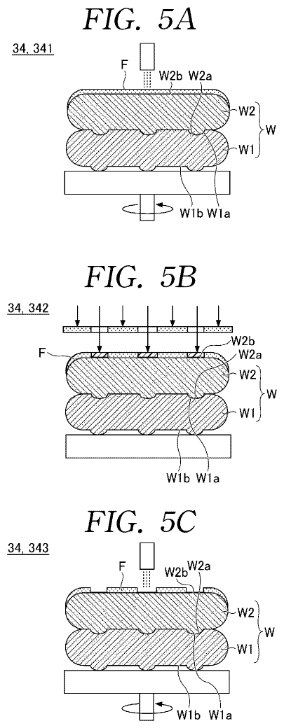

Now, with reference to FIG. 5A to FIG. 5C, an example of the formation of the film F using a photosensitive material will be described. A film forming apparatus 34 includes, for example, a coating device 341 shown in FIG. 5A, an exposure device 342 shown in FIG. 5B, and a developing device 343 shown in FIG. 5C.

The coating device 341 coats the photosensitive material on the entire non-bonding surface W2b of the second substrate W2 to form the film F on the entire non-bonding surface W2b of the second substrate W2. The coating device 341 is, for example, a spin coater, and it drops the photosensitive material onto a center of the non-bonding surface W2b of the second substrate W2 being rotated, allowing the photosensitive material to be diffused on the entire non-bonding surface W2b by a centrifugal force. The thickness of the film F can be controlled by adjusting the type (for example, quality or viscosity) of the photosensitive material, coating conditions (for example, a coating amount or a rotation speed), or solidification conditions (for example, a drying temperature). The thickness of the film F can also be controlled by adjusting a repetition number of the coating of the photosensitive material.

The exposure device 342 exposes a portion of the film F. The photosensitive material is of a positive type in which the exposed portion is removed by development, but it may be of a negative type in which the exposed portion remains after the development. The exposure device 342 exposes a portion of the film F such that the film F remains at a position where the thickness t2 of the second substrate W2 is the minimum while the film F is not left at a position where the thickness t2 of the second substrate W2 is the maximum. The exposure device 342 exposes light in a square grid pattern along the plurality of streets S2 or in an island shape for each device area A2 by using, for example, a light blocking film having an aperture pattern.

The developing device 343 develops the film F exposed in the exposure device 342. The position of the film F remaining after the development is controlled by adjusting an exposure position. The developing device 343 is, for example, a spin developer, and it drops a developing liquid onto the center of the non-bonding surface W2b of the second substrate W2 being rotated, allowing the developing liquid to be diffused on the entire non-bonding surface W2b by a centrifugal force. Further, the developing device 343 may be a spray developing device, a dip developing device, etc.

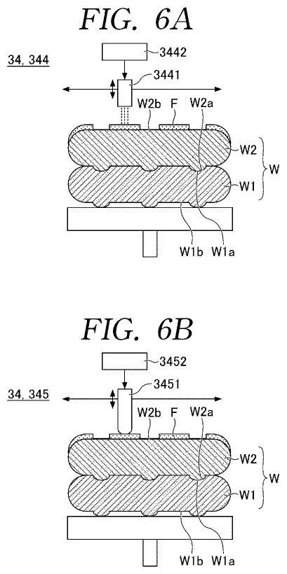

Now, referring to FIG. 6A and FIG. 6B, an example of the formation of the film F using an ink material will be described. The film forming apparatus 34 is equipped with, for example, a coating device 344 shown in FIG. 6A or a coating device 345 shown in FIG. 6B.

The coating device 344 shown in FIG. 6A includes an inkjet head 3441 configured to discharge an ink material, and a moving mechanism 3442 configured to move the inkjet head 3441 relative to the second substrate W2. A position where the film F is formed is controlled by adjusting a discharge position of the ink material. The inkjet head 3441 may have a plurality of nozzles, and may be configured to independently discharge different ink materials from the nozzles. The viscosity of the ink material or the size of particles contained in the ink material may be varied.

The coating device 345 shown in FIG. 6B includes an ink pen 3451 configured to coat an ink material, and a moving mechanism 3452 configured to move the ink pen 3451 relative to the second substrate W2. A position where the film F is formed is controlled by adjusting an coating position of the ink material. The coating device 345 may have a plurality of ink pens 3451, and may be configured to independently discharge different ink materials from the ink pens 3451. The viscosity of the ink material or the size of particles contained in the ink material may be varied.

These coating devices 344 and 345 coat the ink material on a portion of the non-bonding surface W2b of the second substrate W2, thereby forming the film F on the portion of the non-bonding surface W2b of the second substrate W2. The coating devices 344 and 345 form the film F at a position where the thickness t2 of the second substrate W2 is the minimum, whereas they do not form the film F at a position where the thickness t2 of the second substrate W2 is the maximum. When using the ink material, it is easier to correct the formation position of the film F as compared to when using the photosensitive material. The thickness of the film F can be controlled by adjusting a coating amount of the ink material, the viscosity of the ink material, or the size of the particles contained in the ink material. The thickness of the film F can also be controlled by adjusting a repetition number the coating of the ink material.

The film forming apparatus 34 according to the above-described exemplary embodiment forms the film F on a portion of the non-bonding surface W2b of the second substrate W2. However, the film forming apparatus 34 may form the film F on the entire non-bonding surface W2b. In such a case, the film F needs to be formed thicker on a portion of the non-bonding surface W2b than on another portion of the non-bonding surface W2b. The film forming apparatus 34 sets the thickness of the film F to be smaller at a position where the thickness of the second substrate W2 is larger.

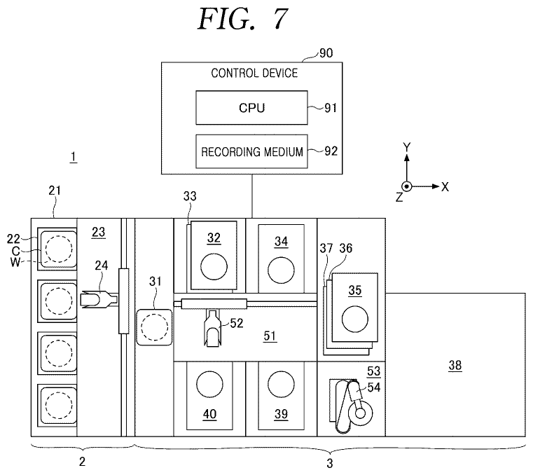

Now, referring to FIG. 7, a substrate processing apparatus 1 according to the exemplary embodiment will be discussed. The substrate processing apparatus 1 forms a film on a portion of the non-bonding surface W2b of the second substrate W2 of the combined substrate W, or forms the film F thicker on a portion of the non-bonding surface W2b than on another portion thereof. In this state, the substrate processing apparatus 1 thins the first substrate W1. The first substrate W1 and the second substrate W2 are bonded to each other in advance, and the combined substrate W is brought into the substrate processing apparatus 1. The substrate processing apparatus 1 is equipped with a carry-in/out station 2, a processing station 3, and the control device 90. Here, it should be noted that the substrate processing apparatus 1 needs to be equipped with the film forming apparatus 34 and the control device 90 at least.

The carry-in/out station 2 is provided with a placing table 21. The cassette C is placed on the placing table 21. The cassette C accommodates therein a plurality of combined substrates W at a certain interval therebetween in a vertical direction. The placing table 21 includes a plurality of placement plates 22 arranged in a row in the Y-axis direction. The cassette C is disposed on each of the plurality of placement plates 22. The number of the placement plates 22 is not particularly limited. Likewise, the number of the cassettes C is not particularly limited.

The carry-in/out station 2 has a first transfer area 23 disposed between the placing table 21 and the processing station 3, and a first transfer device 24 configured to transfer the combined substrate W in the first transfer area 23. The first transfer device 24 includes a transfer arm configured to hold the combined substrate W. The transfer arm is movable in horizontal directions (in both the X-axis direction and the Y-axis direction) and a vertical direction, and pivotable around a vertical axis. Here, the number of the first transfer arm(s) may be one or more.

The processing station 3 includes, for example, a first transition apparatus 31, a measuring apparatus 32, a first inverting apparatus 33, a film forming apparatus 34, a second inverting apparatus 35, a second transition apparatus 36, an alignment apparatus 37, the thinning apparatus 38, a first cleaning apparatus 39, and a second cleaning apparatus 40. The layout and the number of these apparatuses 31 to 40 are not limited to those shown in FIG. 7.

The first transition apparatus 31 and the second transition apparatus 36 temporarily accommodate the combined substrate W therein. The measuring apparatus 32 measures a thickness distribution of the second substrate W2. The first inverting apparatus 33 and the second inverting apparatus 35 invert the combined substrate W. The film forming apparatus 34 forms the film F on a portion of the non-bonding surface W2b of the second substrate W2. The alignment apparatus 37 detects a center of the combined substrate W. The alignment apparatus 37 may detect the crystal orientation of the first substrate W1 or the second substrate W2 in addition to the center of the combined substrate W, and may specifically detect a notch or orientation flat indicating the crystal orientation of the first substrate W1 or the second substrate W2. The thinning apparatus 38 thins the first substrate W1. The first cleaning apparatus 39 and the second cleaning apparatus 40 clean the combined substrate W.

The processing station 3 includes a second transfer area 51 disposed opposite to the first transfer area 23 with the first transition apparatus 31 therebetween, and a second transfer device 52 configured to transfer the combined substrate W in the second transfer area 51. The second transfer device 52 is configured in the same manner as the first transfer device 24, and serves to transfer the combined substrate W between the plurality of apparatuses adjacent to the second transfer area 51.

Further, the processing station 3 has a third transfer area 53 surrounded on three sides by the alignment apparatus 37, the thinning apparatus 38, and the first cleaning apparatus 39; and a third transfer device 54 configured to transfer the combined substrate W in the third transfer area 53. The third transfer device 54 is configured in the same manner as the first transfer device 24, and serves to transfer the combined substrate W between the plurality of apparatuses adjacent to the third transfer area 53.

The control device 90 is, for example, a computer, and includes a CPU (Central Processing Unit) 91, and a recording medium 92 such as a memory. The recording medium 92 stores therein a program for controlling various processings performed in the substrate processing apparatus 1. The control device 90 controls an operation of the substrate processing apparatus 1 by causing the CPU 91 to execute the program stored in the recording medium 92.

Now, operations of the substrate processing apparatus 1 will be described. The following operations are performed under the control of the control device 90. First, the first transfer device 24 takes out the combined substrate W from the cassette C, and transfers it to the first transition apparatus 31. Subsequently, the second transfer device 52 takes out the combined substrate W from the first transition apparatus 31, and transfers it to the measuring apparatus 32.

Next, the measuring apparatus 32 measures the thickness distribution of the second substrate W2, as shown in FIG. 3A. The measurement data includes the coordinates on the non-bonding surface W2b of the second substrate W2; and the thickness t2 of the second substrate W2 for each coordinate. The measuring apparatus 32 outputs the measurement data to the control device 90. The control device 90 receives the measurement data outputted by the measuring apparatus 32. After the measuring apparatus 32 measures the thickness distribution of the second substrate W2, the second transfer device 52 takes out the combined substrate W from the measuring apparatus 32, and transfers it to the first inverting apparatus 33.

Then, the first inverting apparatus 33 inverts the combined substrate W upside down, thus allowing the non-bonding surface W2b of the second substrate W2 to face up. Thereafter, the second transfer device 52 takes out the combined substrate W from the first inverting apparatus 33, and transfers it to the film forming apparatus 34. In addition, although the measuring apparatus 32 measures the thickness distribution of the second substrate W2 with the non-bonding surface W2b of the second substrate W2 facing downwards in the present exemplary embodiment, the thickness distribution of the second substrate W2 may be measured in the state that the non-bonding surface W2b faces upwards. In this case, the first inverting apparatus 33 is not necessary, and the second transfer device 52 transfers the combined substrate W taken out from the measuring apparatus 32 to the film forming apparatus 34.

Afterwards, the film forming apparatus 34 forms the film F on a portion of the non-bonding surface W2b of the second substrate W2, as shown in FIG. 3B. As illustrated in FIG. 4, the film forming apparatus 34 forms the film F in the square grid pattern along the plurality of streets S2 (see FIG. 2) when viewed from a direction perpendicular to the bonding surface W2a. Although not shown, the film forming apparatus 34 may form the film F in the island shape for each device area A2 when viewed in the direction perpendicular to the bonding surface W2a.

The film forming apparatus 34 may form the film F on the entire non-bonding surface W2b of the second substrate W2. In this case, the film F needs to be formed thicker on a portion of the non-bonding surface W2b than on another portion. When viewed from the direction perpendicular to the bonding surface W2a, the film F may be formed thicker on the plurality of streets S2 than in the device areas A2, or may be formed thicker in each device area than on the plurality of streets S2. After the formation of the film F, the second transfer device 52 takes out the combined substrate W from the film forming apparatus 34, and transfers it to the second inverting apparatus 35.

Next, the second inverting apparatus 35 inverts the combined substrate W upside down, thus allowing the non-bonding surface W2b of the second substrate W2 to face down. Thereafter, the second transfer device 52 takes out the combined substrate W from the second inverting apparatus 35, and transfers it to the second transition apparatus 36. Afterwards, the second transfer device 52 takes out the combined substrate W from the second transition apparatus 36, and transfers it to the alignment apparatus 37.

Subsequently, the alignment apparatus 37 detects the center of the combined substrate W by detecting, for example, an outer periphery of the combined substrate W. The alignment apparatus 37 may also detect the crystal orientation of the first substrate W1 or the second substrate W2, and may specifically detect he notch or the like. Then, the third transfer device 54 takes out the combined substrate W from the alignment apparatus 37, and transfers it to the thinning apparatus 38.

The control device 90 controls the third transfer device 54 based on the detection result of the alignment apparatus 37 to align the center of the combined substrate W with the center of the substrate holder 381 of the thinning apparatus 38. In addition, the control device 90 controls the third transfer device 54 based on the detection result of the alignment apparatus 37 to align the crystal orientation of the first substrate W1 or the second substrate W2 to a required orientation in a rotating coordinate system that is rotated together with the substrate holder 381 of the thinning apparatus 38.

Next, the thinning apparatus 38 thins the first substrate W1. For example, as shown in FIG. 3C, the thinning apparatus 38 grinds the first substrate W1 by bringing the grindstone 382 into contact with the combined substrate W from the opposite side (for example, the upper side) to the substrate holder 381 in the state that the substrate holder 381 is holding the combined substrate W through the film F. At this time, the combined substrate W is transformed according to the opening pattern of the film F or the thickness distribution of the film F. As a result, the unevenness in the thickness t1 of the first substrate W1 after being thinned is reduced. Thereafter, the third transfer device 54 takes out the combined substrate W from the thinning apparatus 38, and transfers it to the first cleaning apparatus 39.

Then, the first cleaning apparatus 39 cleans the combined substrate W to remove a particle such as a processing residue. The first cleaning apparatus 39 may remove the film F. For example, the first cleaning apparatus 39 removes the film F by dissolving the film F in a solvent. After the combined substrate W is dried, the second transfer device 52 takes out the combined substrate W from the first cleaning apparatus 39, and transfers it to the second cleaning apparatus 40.

Subsequently, the second cleaning apparatus 40 removes a processing mark by etching the combined substrate W. After the combined substrate W is dried, the second transfer device 52 takes out the combined substrate W from the second cleaning apparatus 40, and transfers it to the measuring apparatus 32. The measuring apparatus 32 measures the thickness distribution of the first substrate W1 after being thinned, and sends the measurement data to the control device 90.

The control device 90 receives the measurement data sent by the measuring apparatus 32. If the unevenness in the thickness t1 of the first substrate W1 after being thinned falls out of an allowable range, the control device 90 corrects the thickness distribution of the film F or the formation position of the film F on the non-bonding surface W2b of the second substrates W2 such that the unevenness in the thickness t1 of the first substrate W1 after the next thinning process may fall within the allowable range.

Afterwards, the second transfer device 52 takes out the combined substrate W from the measuring apparatus 32, and transfers it to the first transition apparatus 31. Subsequently, the first transfer device 24 takes out the combined substrate W from the first transition apparatus 31, and accommodates it in the cassette C. Thereafter, the combined substrate W is carried out from the substrate processing apparatus 1 while being accommodated in the cassette C.

Further, although the first substrate W1 and the second substrate W2 are bonded in advance and the combined substrate W is carried into the substrate processing apparatus 1, the first substrate W1 and the second substrate W2 may be bonded inside the substrate processing apparatus 1. That is, the substrate processing apparatus 1 may be equipped with a bonding apparatus, and this bonding apparatus may bond the first substrate W1 and the second substrate W2. When the substrate processing apparatus 1 has the bonding apparatus, the measurement of the thickness distribution of the second substrate W2 may be performed before the bonding of the first substrate W1 and the second substrate W2. Additionally, when the substrate processing apparatus 1 has the bonding apparatus, the formation of the film F may be performed before the bonding of the first substrate W1 and the second substrate W2.

The substrate processing apparatus 1 does not need to be provided with the measuring apparatus 32. The measuring apparatus 32 may be disposed outside the substrate processing apparatus 1, and may transmit the measurement data to the control device 90. The thickness distribution of the second substrate W2 tends to be the same for each lot (for example, the width of the street S2, the pitch of the street S2, or the type of the device D2) of the second substrates W2. Accordingly, the control device 90 may previously store therein the coordinates on which the film F is to be formed, and may control the film forming apparatus 34 according to the stored data. Therefore, it is also possible not to use the measuring apparatus 32 at all. Additionally, the street S2 and the device D2 do not need to be formed on the second substrate W2. The film F may be formed based only on the measurement data of the measuring apparatus 32, regardless of the positions of the street S2 and the device D2.

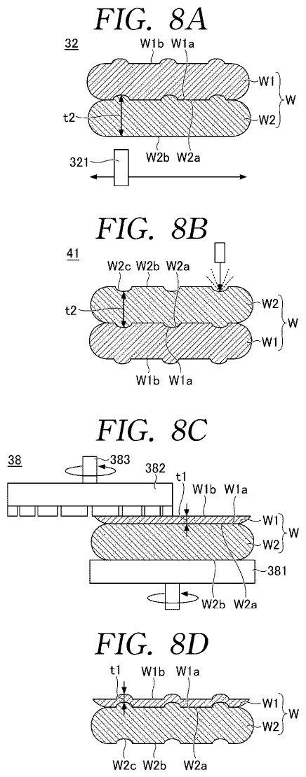

Now, referring to FIG. 8A to FIG. 8D, a substrate processing method according to a modification example will be discussed. In the above-described exemplary embodiment, the film F is formed on a portion of the non-bonding surface W2b of the second substrate W2 before the first substrate W1 is thinned. In the present modification example, however, a recess W2c is formed in a portion of the non-bonding surface W2b of the second substrate W2 before the first substrate W1 is thinned. Below, distinctive features of the modification example will be mainly explained.

First, as illustrated in FIG. 8A, the measuring apparatus 32 measures the thickness distribution of the second substrate W2. Although the thickness distribution of the second substrate W2 is measured after the bonding of the first substrate W1 and the second substrate W2 in the present modification example, it may be possible to measure the thickness distribution of the second substrate W2 before the bonding of the first substrate W1 and the second substrate W2.

Next, as shown in FIG. 8B, the recess W2c is formed in a portion of the non-bonding surface W2b of the second substrate W2 based on the thickness distribution of the second substrate W2. The formation of the recess W2c is performed under the control of the control device 90. The recess W2c is formed at a position where the thickness t2 of the second substrate W2 is the maximum, whereas the recess W2c is not formed at a position where the thickness t2 of the second substrate W2 is the minimum.

For example, when the thickness of the second substrate W2 in the device area A2 is larger than the thickness of the second substrate W2 on the street S2, the control device 90 forms the recess W2c in the shape of the island in each device area A2. Further, when the thickness of the second substrate W2 on the street S2 is larger than the thickness of the second substrate W2 in the device area A2, the control device 90 forms the recess W2c in the square grid pattern along the plurality of streets S2.

The depth of the recess W2c varies depending on the difference (TTV) between the maximum value and minimum value of the thickness t2 of the second substrate W2. The larger the TTV is, the larger the depth of the recess W2c is set to be. Furthermore, although the recess W2c is formed after the bonding of the first substrate W1 and the second substrate W2 in the present modification example, the recess W2c may be formed before the bonding of the first substrate W1 and the second substrate W2.

To form the recess W2c, a laser processing apparatus 41, for example, is used. The laser processing apparatus 41 performs an ablation processing on the second substrate W2 by radiating a laser beam to a position where the recess W2c is to be formed. The position of the recess W2c is controlled by the radiation position of the laser beam. The depth of the recess W2c is controlled by the radiation intensity or the radiation time of the laser beam. The laser processing apparatus 41 is provided in the substrate processing apparatus 1 instead of the film forming apparatus 34 of FIG. 1.

Next, as shown in FIG. 8C, with the recess W2c formed in a portion of the non-bonding surface W2b of the second substrate W2, the thinning apparatus 38 thins the first substrate W1 previously bonded to the second substrate W2. The substrate holder 381 comes into contact with the non-bonding surface W2b of the second substrate W2 and attracts it, thus elastically transforming the second substrate W2 to thereby planarize the non-bonding surface W2b of the second substrate W2.

As a result, the bonding surface W2a of the second substrate W2 is planarized, and the bonding surface W1a of the first substrate W1 is also planarized. In this state, the thinning apparatus 38 processes the non-bonding surface W1b of the first substrate W1 parallel to the bonding surface W1a of the first substrate W1 by using the grindstone 382. Accordingly, the thickness t1 of the first substrate W1 after being thinned becomes uniform as illustrated in FIG. 8D. As compared to the reference embodiment, the unevenness in the thickness t1 of the first substrate W1 after being thinned can be reduced.

In addition, a non-illustrated laser processing apparatus may be used to thin the first substrate W1. The laser processing apparatus forms a modification layer inside the first substrate W1. A plurality of such modification layers are formed at certain intervals in the radial direction and the circumferential directions of the first substrate W1. By separating the first substrate W1 based on the plurality of modification layers, the first substrate W1 can be thinned. In this case as well, if the bonding surface W2a of the second substrate W2 is planarized by elastically transforming the second substrate W2, and then, the non-bonding surface W1b of the first substrate W1 is planarized, the modification layer can be formed at a certain depth from the non-bonding surface W1b, so that the unevenness in the thickness t1 of the first substrate W1 after being thinned can be reduced.

So far, the exemplary embodiment of the substrate processing apparatus and the substrate processing method according to the present disclosure have been described. However, the present disclosure is not limited to the above-described exemplary embodiment or the like. Various changes, corrections, replacements, addition, deletion and combinations may be made within the scope of the claims, and all of these are included in the scope of the inventive concept of the present disclosure.

This application claims priority to Japanese Patent Application No. 2021-174767, filed on Oct. 26, 2021, which application is hereby incorporated by reference in their entirety.

### EXPLANATION OF CODES

1: Substrate processing apparatus
34: Film forming apparatus (film forming device)
90: Control device (Controller)
F: Film
W: Combined substrate
W1: First substrate
W2: Second substrate
W2b: Non-bonding surface

1. A substrate processing apparatus, comprising:
a film forming device configured to form a film on a non-bonding surface of a second substrate, which has a bonding surface bonded to a first substrate to be thinned and the non-bonding surface opposite to the bonding surface; and
a controller configured to control the film forming device,
wherein the controller performs a control of forming the film on a portion of the non-bonding surface or forming the film thicker on a portion of the non-bonding surface than on another portion thereof, based on a thickness distribution of the second substrate.

2. The substrate processing apparatus of claim 1,
wherein the second substrate has, on the bonding surface thereof, multiple streets arranged in a square grid pattern, and devices formed in device areas partitioned by the multiple streets,
wherein when viewed from a direction perpendicular to the bonding surface, the controller performs a control of forming the film in the square grid pattern along the multiple streets, forming the film thicker on the multiple streets than in the device areas, forming the film in an island shape in each device area, or forming the film thicker in each device area than on the multiple streets.

3. The substrate processing apparatus of claim 1,
wherein the film forming device comprises a coating device configured to coat a photosensitive material on the non-bonding surface of the second substrate to form the film on the non-bonding surface of the second substrate, an exposure device configured to expose a portion of the film, and a developing device configured to develop the film exposed in the exposure device.

4. The substrate processing apparatus of claim 1,
wherein the film forming device comprises a coating device configured to coat an ink material on the non-bonding surface of the second substrate to form the film.

5. The substrate processing apparatus of claim 1,
wherein the controller acquires measurement data of the thickness distribution of the second substrate, and performs a control of allowing the film not to be formed at a position where a thickness of the second substrate is of a maximum value, or making a thickness of the film smaller at a position where the thickness of the second substrate is larger.

6. The substrate processing apparatus of claim 5, further comprising:
a measuring device configured to measure the thickness distribution of the second substrate.

7. The substrate processing apparatus of claim 1, further comprising:
a thinning device configured to thin the first substrate previously bonded to the second substrate in a state that the film is formed on the non-bonding surface of the second substrate.

8. The substrate processing apparatus of claim 7, further comprising:
a cleaning device configured to remove the film after the first substrate is thinned by the thinning device.

9. A substrate processing apparatus, comprising:
a thinning device configured to thin, in a combined substrate including a first substrate and a second substrate which is bonded to the first substrate, the second substrate having a bonding surface bonded to the first substrate and a non-bonding surface opposite to the bonding surface, the first substrate of the combined substrate,
wherein the thinning device comprises:
a substrate holder configured to attract the combined substrate via a film formed on a portion of the non-bonding surface of the second substrate, or a film formed thicker on a portion of the non-bonding surface than on another portion thereof; and
a grindstone driving device configured to bring a grindstone into contact with the first substrate of the combined substrate attracted to the substrate holder.

10. A substrate processing method, comprising:
forming a film on a non-bonding surface of a second substrate, which has a bonding surface bonded to a first substrate to be thinned and the non-bonding surface opposite to the bonding surface,
wherein the film is formed on a portion of the non-bonding surface, or the film is formed thicker on a portion of the non-bonding surface than on another portion thereof, based on a thickness distribution of the second substrate.

11. The substrate processing method of claim 10,
wherein the second substrate has, on the bonding surface thereof, multiple streets arranged in a square grid pattern, and devices formed in device areas partitioned by the multiple streets, and
when viewed from a direction perpendicular to the bonding surface, the film is formed in the square grid pattern along the multiple streets, the film is formed thicker on the multiple streets than in the device areas, the film is formed in an island shape in each device area, or the film is formed thicker in each device area than on the multiple streets.

12. The substrate processing method of claim 10, further comprising:
coating a photosensitive material on the non-bonding surface of the second substrate to form the film on the non-bonding surface of the second substrate;
exposing a portion of the film; and
developing the exposed film.

13. The substrate processing method of claim 10, further comprising:
coating an ink material on the non-bonding surface of the second substrate to form the film.

14. The substrate processing method of claim 10, further comprising:
acquiring measurement data of the thickness distribution of the second substrate; and
allowing the film not to be formed at a position where a thickness of the second substrate is of a maximum value, or making a thickness of the film smaller at a position where the thickness of the second substrate is larger.

15. The substrate processing method of claim 10, further comprising:
thinning, the first substrate previously bonded to the second substrate in a state that with the film is formed on a portion of the non-bonding surface of the second substrate.

16. The substrate processing method of claim 15, further comprising:
removing the film after the thinning of the first substrate.

17. A substrate processing method including thinning, in a combined substrate including a first substrate and a second substrate which is bonded to the first substrate, the second substrate having a bonding surface bonded to the first substrate and a non-bonding surface opposite to the bonding surface, the first substrate of the combined substrate, the substrate processing method comprising:
attracting the combined substrate to a substrate holder via a film formed on a portion of the non-bonding surface of the second substrate, or a film formed thicker on a portion of the non-bonding surface than on another portion thereof; and
grinding the first substrate of the combined substrate attracted to the substrate holder by a grindstone.
